(19) United States
(12) Patent Application Publication
(10) Pub. No.: US 2013/0342263 A1
(43) Pub. Date: Dec. 26, 2013

(54) HEATER FOR SEMICONDUCTOR DEVICE

(71) Applicant: Thorsten MEYER, Muenchen (DE)

(72) Inventor: Thorsten MEYER, Muenchen (DE)

(21) Appl. No.: 13/532,948

(22) Filed: Jun. 26, 2012

(51) Int. Cl. H01L 23/34; H01L 21/00; H03K 17/14

(52) U.S. Cl. 327/378; 257/712; 438/382; 257/E23.081; 257/E21.001

(57) ABSTRACT

Representative implementations of devices and techniques provide heating for a semiconductor device. A heating element is arranged to be located proximate to the semiconductor device and to increase a temperature of at least a portion of the semiconductor device during operation of the semiconductor device.

### BACKGROUND

One common application of a modern semiconductor power device is a repetitive switching of inductive loads. In such use cases, a semiconductor device may have to survive billions of switching cycles, and the thermal effects associated with them. For example, some semiconductor devices use multiple interleaved connecting wires (or leads) as part of the application. Common failures include the progressive degradation of the connecting wires and cracks in the dielectric separating the wires due to lateral temperature gradients at various locations of the device. Shorts may occur as the cracks fill up with metal due to cyclic thermo-mechanical stress. The cracks are often caused by pressure which builds up due to lateral material transport along the metal lines. The transport is possible above a certain temperature, and can be driven by the lateral temperature gradients along the metal lines.

Lateral temperature gradients are differences in temperature between adjacent portions of a semiconductor device, and may be described with a slope. The steeper the slope, the greater the temperature change per area, thus, the greater the lateral temperature gradient at that area of the semiconductor. Lateral temperature gradients may occur at or near areas of a semiconductor device where switching activity occurs, resulting in heat. Accordingly, lateral temperature gradients may be the greatest at or near locations of concentrated switching activity.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items.

For this discussion, the devices and systems illustrated in the figures are shown as having a multiplicity of components. Various implementations of devices and/or systems, as described herein, may include fewer components and remain within the scope of the disclosure. Alternately, other implementations of devices and/or systems may include additional components, or various combinations of the described components, and remain within the scope of the disclosure.

FIG. 1 is a schematic drawing of an example heating element, located proximate to a semiconductor device, according to an implementation.

FIG. 2 is a graph showing example temperature curves of a semiconductor, with and without a heating element.

FIG. 3A is schematic drawing of an example heating element implemented with a semiconductor device, including a pair of switches, according to an implementation.

FIG. 3B is schematic drawing of the example heating element of FIG. 3A, including components for energizing the heating element, according to an implementation.

FIG. 4A is a schematic drawing illustrating example metallization layers arranged for energizing the heating element, according to an implementation.

FIG. 4B shows an example circuit diagram of a heating element, including a pair of switches arranged for energizing the heating element, according to an implementation.

FIG. 5 is a flow diagram illustrating an example process for heating a semiconductor device, according to an implementation.

### DETAILED DESCRIPTION

### Overview

Representative implementations of devices and techniques provide heating for a semiconductor device. A heating element is arranged to be located proximate to the semiconductor device and to increase a temperature of at least a portion of the semiconductor device during operation of the semiconductor device. In an implementation, heating a portion of the semiconductor device includes moving or re-distributing a lateral temperature gradient from the portion of the semiconductor device, where it can potentially cause damage to the semiconductor device, to a location away from the semiconductor device (or to another portion of the semiconductor device), where it is less likely to cause damage.

In one implementation, a heating element is arranged to be located proximate to one or more edges of the semiconductor device, and is arranged to increase the temperature of the one or more edges of the semiconductor device during operation of the semiconductor device. In one example, the heating device may be located around the periphery of the semiconductor device.

Various implementations and arrangements for heating a semiconductor device are discussed in this disclosure. Techniques and devices are discussed with reference to example semiconductor devices given in example implementations and illustrated in the figures. For example, the discussion and figures make reference to power transistor devices. However, this is not intended to be limiting, and is for ease of discussion and illustrative convenience. The techniques and devices discussed may be applied to any of various semiconductor designs, structures, and the like (e.g., transistors, thyristors, diodes, etc.), and remain within the scope of the disclosure.

Implementations are explained in more detail below using a plurality of examples. Although various implementations and examples are discussed here and below, further implementations and examples may be possible by combining the features and elements of individual implementations and examples.

### Example Heating Element

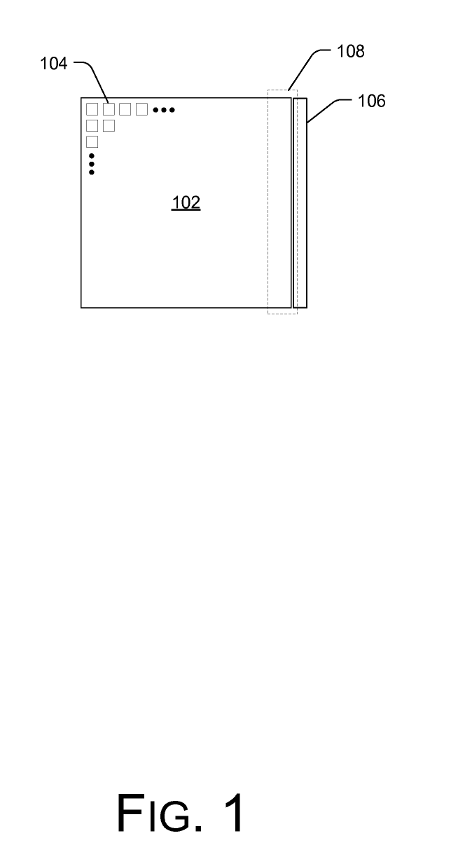

FIG. 1 is a schematic drawing of an example semiconductor device 102, according to an implementation, wherein the techniques and devices described herein may be applied. In various implementations, the semiconductor device 102 may comprise one or more transistors (e.g., insulated gate bipolar transistor (IGBT), junction field-effect transistor (JFET), metal-oxide-semiconductor field-effect transistor (MOSFET), double-diffused metal-oxide-semiconductor (DMOS), metal-insulator-semiconductor FET (MISFET), metal-semiconductor FET (MESFET), insulated-gate FET (IGFET), high-electron mobility transistor (HEMT) or (HFET), modulation-doped FET (MODFET), etc.), other semiconductor devices (e.g., diodes, thyristors, etc.), or combinations of the same, and remain within the scope of the disclosure. The transistors and/or other semiconductor devices (“device cells 104”) may be vertically arranged devices, laterally arranged devices, or the like.

In one implementation, the semiconductor device 102 is comprised primarily of silicon. In alternate implementations, the semiconductor device 102 is comprised primarily of other semiconductor materials (e.g., germanium, gallium arsenide, gallium nitride, etc.), or combinations of the same.

As shown in FIG. 1, a heating element 106 may be located proximate to the semiconductor device 102, and used to increase a temperature of at least a portion of the semiconductor device 102 during operation of the semiconductor device 102. In one implementation, as shown in FIG. 1, the heating element 106 is arranged to be located proximate to one or more edges of the semiconductor device 102. In the implementation, the heating element 106 is used to increase a temperature of the one or more edges of the semiconductor device 102 during operation of the semiconductor device 102. In an alternate implementation, the heating element 106 may be located within the interior area of the semiconductor device 102, and used to increase the temperature of a portion of the interior area of the semiconductor device 102. For example, in an implementation, the heating element 106 is realized as a device within the body of the semiconductor device 102.

The dashed outline 108 shows an example portion of the semiconductor device 102 that may be heated by the heating element 106, for example, when the heating element 106 is located at an edge of the semiconductor device 102. The heated portion of the semiconductor device 102 is generally adjacent to the heating element 106, wherever the heating element 106 is located, since the heating element 106 provides heating (i.e., increase in temperature) to the portion of the semiconductor device 102.

In various implementations, the heating element 106 is arranged to reduce a lateral temperature gradient of a portion of the semiconductor device 102 during operation of the semiconductor device 102. For example, the heating element 106 may be arranged to provide a substantially homogeneous temperature distribution across the semiconductor device 102. For instance, in the example shown in FIG. 1, a temperature gradient may be present at an edge of the semiconductor device 102, for example, without the heating element 106. However, with the heating element 106, the whole area of the semiconductor device 102, including the edges, can have a substantially homogeneous temperature distribution.

In an implementation, the heating element 106 is arranged to relocate the lateral temperature gradient associated with a portion of the semiconductor device 102 a preselected distance. For example, the heating element 106 may be arranged to move the lateral temperature gradient (or the greatest lateral temperature gradient) to a location outside the periphery of the semiconductor device 102. In that way, the damaging effects of the temperature gradient are reduced or eliminated with respect to the semiconductor device 102.

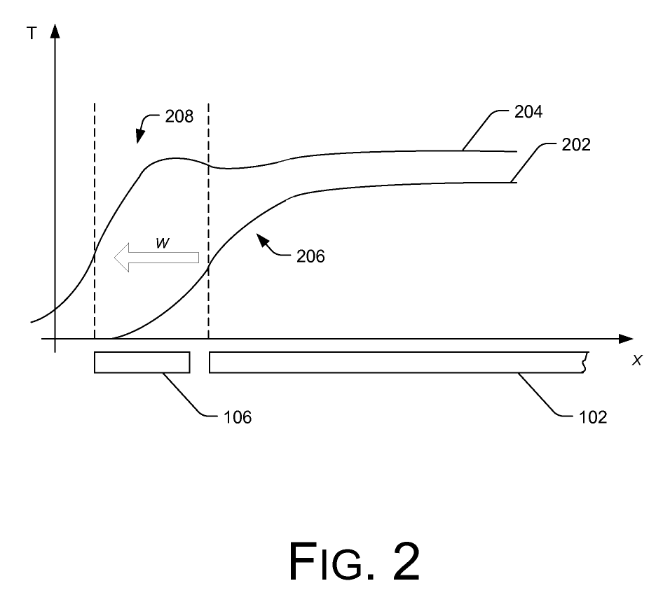

FIG. 2 is a graph showing example temperature curves (202 and 204) of a semiconductor device 102, with and without a heating element 106 located at an edge of the semiconductor device 102, for example. The graph shows a temperature T of the semiconductor device 102 (shown in profile) as a function of a distance x. The first temperature curve 202, without the heating element 106, includes a lateral temperature gradient (at 206) within the area (at the edge portion) of the semiconductor device 102.

The second temperature curve 204, with the heating element 106 increasing the temperature of the edge portion of the semiconductor device 102, for example, shows the greatest lateral temperature gradient (at 208) outside the area of the semiconductor device 102. The result is a more homogeneous temperature distribution within the area of the semiconductor device 102. In an implementation, as shown, the heating element 106 moves (e.g., relocates, redistributes, etc.) the lateral temperature gradient a distance substantially equal to the width w of the heating element.

In an implementation, the heating element 106 is switched on concurrently with the semiconductor device 102 and is switched off concurrently with the semiconductor device 102. This allows the heating element 106 to heat the portion 108 of the semiconductor device 102 when the semiconductor device 102 is generating heat and subject to the lateral temperature gradient (i.e., when it is switching a load, passing a current, in operation, etc.).

In another implementation, the heating element 106 has a power density substantially equal to a power density of the semiconductor device 102 during operation of the semiconductor device 102. Having a similar power density to the semiconductor device 102 during operation allows the heating element 106 to heat a portion of the semiconductor device 102 to a temperature similar to the temperature reached by the semiconductor device 102 during switching. Thus, a substantially homogeneous temperature distribution is achieved across the area of the semiconductor device 102.

In an implementation, the heating element 106 comprises a polysilicon structure. For example, the heating element 106 may comprise one or more polysilicon resistors. In alternate implementations, the heating element 106 is comprised of other materials or combinations of materials. In various implementations, the dimensions (area, cross-section, width, etc.) and/or arrangement (parallel, series, or combination arrangements) of the heating element 106 may be based on the power density of the semiconductor device 102 during operation of the semiconductor device. For example, the dimensions and/or arrangement of the heating element 106 may be arranged to match the power density of the semiconductor device 102 during operation of the semiconductor device 102, to achieve a similar heating response. Accordingly, the material of the heating element 106 may also be selected based on the power density of the semiconductor device 102.

In one implementation, a cross-sectional area of the heating element 106 is based on a preselected distance to relocate the lateral temperature gradient. For example, as discussed above, the lateral temperature gradient may be moved by the heating element 106 a distance substantially equal to the width of the heating element 106. Accordingly, the dimensions of the heating element 106 may be based on a desired distance to move the lateral temperature gradient with respect to the semiconductor device 102.

For example, assuming that a lateral temperature gradient present at each edge of a 1 square millimeter semiconductor device 102 is desired to be moved a distance of 10 microns (to a point outside the area of the semiconductor device 102), then a 10 micron wide heating element 106 may be located proximate to each edge of the semiconductor device 102. For example, the heating element 106 may “encircle” the perimeter of the semiconductor device 102. Thus, in this example, the heating element 106 is a total of 4 mm long (4×1 mm) and 10 microns wide, i.e., having an area of 0.04 mm².

A typical power density for a 1 square millimeter power semiconductor device 102 (a DMOS, for example) is about 50 W/mm², which corresponds to a typical clamping pulse of 1 A at 50V. This means that the heating element 106 can use 2 W of power at 40 mA, with a resistance of 1.25 kΩ, using the full voltage of the pulse, to match the power density of the semiconductor device 102. This can be achieved by coupling 4 heating elements 106 having a resistance of 5 kΩ each in a parallel configuration.

In an example, 4 polysilicon resistors can be used to implement the heating element 106. A typical resistance of polysilicon used in integrated power technologies is 25 Ohms per square. A 5 kΩ polysilicon resistor may be constructed using 200 squares of polysilicon. In one implementation, this can be achieved by meandering a polysilicon wire of 5 micron width along a 1 mm×10 μm area of each edge of the semiconductor device 102. With 10 mA over each of the 4 parallel poly wires, this corresponds to a power density of 100 μW/μm², which is well within the DC power capability of polysilicon wires. In alternate implementations, other materials may be used to implement the heating element(s) 106, and alternate configurations may be employed to achieve the desired results (i.e., matching the power density of the semiconductor device 102 and moving the lateral temperature gradient a desired distance).

The techniques, components, and devices described herein with respect to the heating element 106 are not limited to the illustrations in the figures or the examples discussed, and may be applied to other heating element 106 designs without departing from the scope of the disclosure. In some cases, additional or alternative components may be used to implement the techniques described herein. It is to be understood that a heating element 106 may be implemented as a stand-alone device or as part of another system (e.g., integrated with other components, systems, etc., including the semiconductor device 102).

### Example Implementations

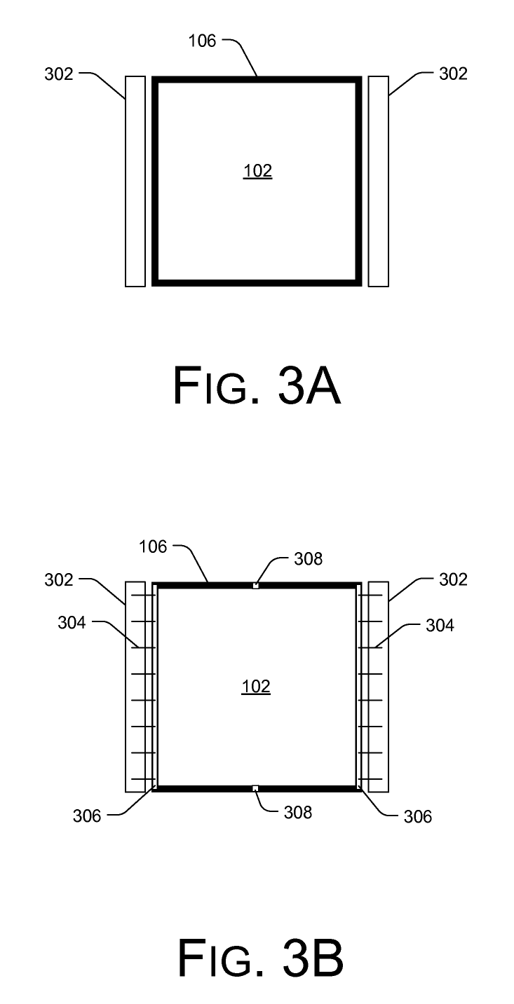

FIG. 3A is schematic diagram of an example heating element 106 implemented with a semiconductor device 102. In the implementation illustrated, the heating element 106 is arranged as a polygonal “ring” encircling the semiconductor device 102. In alternate implementations, the heating element 106 may be a single structure or it may be comprised of multiple structures, as discussed above. For example, the polygonal “ring” arrangement of heating element 106 shown in FIG. 3A may be a single structure, or it may be multiple structures arranged in a ring-like arrangement. In one implementation, the heating element 106 is comprised of multiple structures that extend from vertex to vertex of the polygonal “ring.” In an alternate implementation, the multiple structures extend from a location on one “edge” to another location on another “edge” of the polygonal “ring,” extending through the vertices. Also, in various implementations, the heating element 106 may be located at the perimeter of the semiconductor device 102, or it may be located within the perimeter of the semiconductor device 102. In alternate implementations, the heating element 106 may be embedded within the perimeter ring (or another portion) of the semiconductor device 102.

As discussed above, the heating element 106 may be switched concurrently with the semiconductor device 102. In an implementation, as shown in FIG. 3A, the semiconductor device 102 may include one or more switches 302, arranged to switch the heating element 106. For example, in an implementation, the semiconductor device 102 may include one or more switches 302 coupled to the heating element 106 and arranged to switch on the heating element 106 when the semiconductor device 102 switches on and to switch off the heating element 106 when the semiconductor device 102 switches off.

In one implementation, the switches 302 are transistor devices formed as a part of the semiconductor device 102. In other words, the switches 302 may be formed during the manufacturing process of the semiconductor device 102. In one implementation, one or more switches 302 may be integral to the semiconductor device 102. In alternate implementations, switches 302 may be located and/or arranged differently than illustrated in FIG. 3A. In one implementation, one or more switches 302 may be located within the perimeter of the semiconductor device 102.

FIG. 3B illustrates example connectivity components arranged to couple one or more switches 302 to the heating element 106. Connectivity components may include wires 304 and 306, and the like. The example arrangement shown in FIG. 3B is an illustration of one possible implementation. In various implementations, wires 304 and 306 may be arranged at various locations on and around the semiconductor device 102, the switches 302, and/or the heating element 106.

In the example shown in FIG. 3B, wires 304 (illustrated as short “horizontal” links) connect a switch 302 to the wires 306 (illustrated as long “vertical” links). Wires 306 connect the wires 304 to the heating element 106. In one implementation, wires 306 (and/or wires 304) may be coupled to a power source.

In an implementation, the wires 304 and/or 306 (and the like) in the area of the heating element 106 may be realized to be less sensitive to lateral temperature gradients. For example, the wires (304, 306) may be implemented with narrower gauge wires that are more robust against thermo-mechanical deformation. In another example, the distance between wires (such as wires 304, for example) may be longer to increase the amount of dielectric material between the wires. This may contribute to fewer cracks in the dielectric.

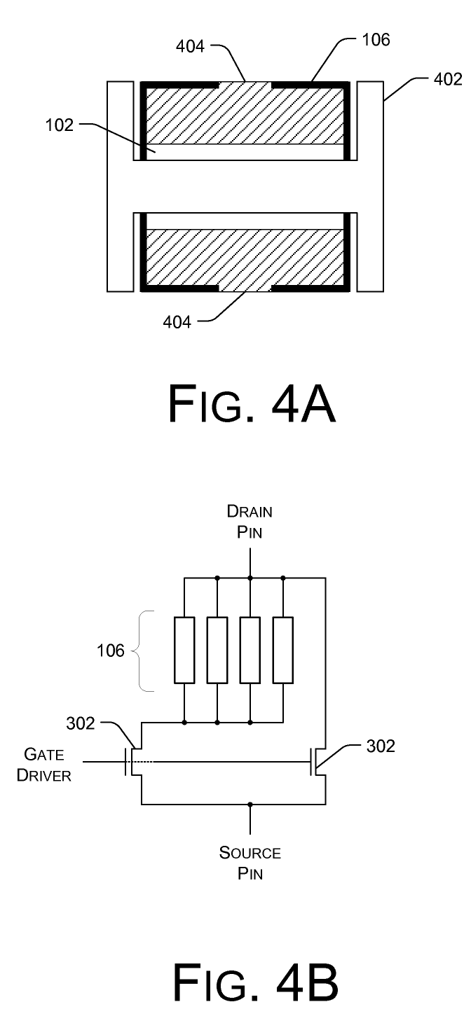

FIG. 4A is a schematic drawing of the semiconductor device 102 and heating element 106, illustrating example metallization layers (402 and 404) arranged for energizing the heating element 106, according to an implementation. In the example shown, one metallization layer 402 may be located over the switches 302, providing a power source to the switches 302. For example, the metallization layer 402 may be coupled to the wires 306 and/or the wires 304. In another implementation, the metallization layer 402 may additionally or alternately be located over one or more of the heating elements 106, providing a power source to the heating element(s) 106. For example, the metallization layer 402 may be coupled to the heating element(s) 106. In an implementation, the metallization layer 402 may be coupled to the source (or emitter) power connection for the semiconductor device 102, for example.

In the example, the other metallization layer 404 may be located over (and coupled to) one or more of the heating elements 106, providing a power source to the heating element(s) 106. In an implementation, the metallization layer 404 may be coupled to the drain (or collector) power connection for the semiconductor device 102, for example.

In an example implementation, the metallization layer 402 is coupled to the source (or emitter) of one or more switches 302. The drain (or collector) of the one or more switches 302 is coupled to the (horizontal) wires 304, which feed the (vertical) wires 306. The current from the wires 306 is fed to the one or more structures of the heating element 106 by way of one or more contacts 308, or the like. The current flows through the one or more structures of the heating element 106 and to the metallization layer 404 at one or more vias (not shown).

In alternate implementations, the wires 304 and 306 and/or the metallization layers 402 and 404 may be arranged in another manner to provide power and/or signaling to the switches 302 and/or the heating element(s) 106. In other implementations, fewer or additional metallization layers may be used with a semiconductor device 102 to energize a heating element 106.

FIG. 4B shows an example circuit diagram of a multiple-structure heating element 106, including a pair of switches 302, according to an implementation. In the circuit diagram of FIG. 4B, the heating element 106 is comprised of four elements in a parallel configuration, for example. Switches 302 are arranged to switch on and off the power supply (from the source and drain pins of the semiconductor device 102) to the heating element 106. In the example arrangement shown in FIG. 4B, the heating element 106 is arranged to switch on when the semiconductor device 102 switches on and to switch off when the semiconductor device 102 switches off.

In alternate implementations, other circuit arrangements, having additional or alternate components, may be employed to achieve the desired switching of the heating element 106.

In an implementation, as mentioned above with respect to FIG. 1, the semiconductor device 102 comprises a plurality of device cells 104 (e.g., transistor cells and/or other semiconductor device cells). In various implementations, the one or more device cells 104 comprising the semiconductor device 102 may be arranged in a matrix (not shown). For example, the device cells 104 may be arranged in a matrix with multiple columns and rows, or the device cells 104 may be arranged in a matrix with a single column or row of device cells 104. Additionally or alternatively, the device cells 104 may be arranged in a matrix with a polygonal arrangement or other geometric form. In a further implementation, the device cells 104 may be arranged in an irregular or eccentric pattern, or combinations of the above, and the like.

In one implementation, the device cells 104 are coupled in parallel, so as to act concurrently in performing via the semiconductor device 102. In alternate implementations, the device cells 104 may be coupled in various combinations of parallel and non-parallel (e.g., series) arrangements. In one implementation, the heating element 106 is located around a periphery of the matrix of parallel device cells 104 and is arranged to increase a temperature of device cells 104 at the periphery of the matrix. In another implementation, the heating element 106 is arranged to move a temperature gradient associated with a periphery of the matrix of device cells 104 to a location outside the periphery of the matrix.

In a further implementation, the device cells 104 include a mix of active cells and inactive cells. For example, active cells may pass a current during operation of the semiconductor device 102, while the inactive cells may not. In one case, the inactive cells may be missing a component, such as a source region, inhibiting them from passing a current when a switching potential is applied to the device cells 104, for example. In other implementations, the inactive cells may be arranged such that they operate in a different mode than the active cells (e.g., a reverse configuration, using a different potential, etc.). In such implementations, only some of the device cells 104 (active cells) may perform switching when triggered; while other device cells 104 (inactive cells) do not.

In an implementation, the active cells and the inactive cells are distributed throughout the matrix of device cells 104 in a systematic distribution. For example, some areas of the semiconductor device 102 may contain a higher concentration of active cells than other areas of the semiconductor device 102. In one implementation, the semiconductor device 102 contains a higher concentration of active cells towards the edge portions of the semiconductor device 102 than the central portions. In the implementation, a greater amount of heat is generated in the edge areas of the semiconductor device 102, due to the higher concentration of active cells there. Additionally, a greater lateral temperature gradient is more likely to be formed in the edge areas of the semiconductor device 102.

In an implementation, the heating element 106 is located proximate to a portion of the device cells 104, and is arranged to increase a temperature of the portion of device cells 104 during operation of the semiconductor device 102. In one example, the heating element 106 is located proximate to a portion of the device cells 104 where there is a high concentration of active cells. For example, a high concentration of active cells may include greater than 50% active cells in one case, or greater than 75% active cells in another case.

In various implementations, additional or alternative components may be used to accomplish the disclosed techniques and arrangements.

### Representative Process

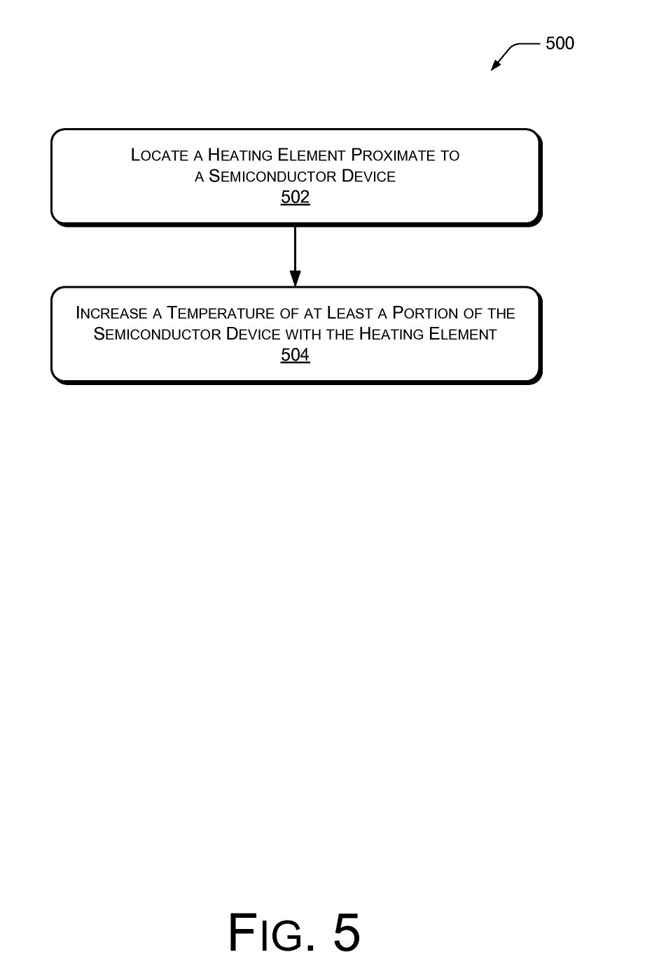

FIG. 5 illustrates a representative process 500 for heating a semiconductor device (such as semiconductor device 102), according to an implementation. The process 500 describes locating a heating element near the semiconductor device to produce a homogeneous temperature distribution across the area of the semiconductor device. The process 500 is described with reference to FIGS. 1-4.

The order in which the process is described is not intended to be construed as a limitation, and any number of the described process blocks can be combined in any order to implement the process, or alternate processes. Additionally, individual blocks may be deleted from the process without departing from the spirit and scope of the subject matter described herein. Furthermore, the process can be implemented in any suitable materials, or combinations thereof, without departing from the scope of the subject matter described herein.

At block 502, the process 500 includes locating a heating element (such as heating element 106) proximate to a semiconductor device. In an implementation, the process includes locating the heating element proximate to one or more of the peripheral edges of the semiconductor device. In other implementations, the process includes locating the heating device proximate to one or more other portions of the semiconductor device.

In one implementation, the process includes forming the heating element as a part of the semiconductor device. For example, the heating element may be formed during the manufacturing process of the semiconductor device. Further, the heating element may be formed to be integral to with the semiconductor device.

At block 504, the process includes increasing a temperature of at least a portion of the semiconductor device with the heating element during operation of the semiconductor device. For example, one or more edge portions may be heated by the heating element during operation of the semiconductor device. This may include heating the portions with each operational pulse (switching pulse, for example) of the semiconductor device. This may also include heating the portions to a substantially equal or similar temperature as that of other portions of the semiconductor device during operation.

In one implementation, the process includes moving a lateral temperature gradient associated with the portion of the semiconductor device a distance substantially equal to a width of the heating element. In another implementation, the process includes moving the lateral temperature gradient from a location associated with the portion of the semiconductor device to a location outside a periphery of the semiconductor device.

In an implementation, the process includes switching on the heating element concurrent to switching on the semiconductor device and switching off the heating element concurrent to switching off the semiconductor device. For example, the heating element may be switched by the same trigger signal(s) as the semiconductor device.

In another implementation, the semiconductor device comprises a matrix of active transistor cells and inactive transistor cells. In one example, the portion of the semiconductor device heated by the heating element has a preselected concentration of active transistor cells within the matrix of active transistor cells and inactive transistor cells. For instance, the preselected concentration of active transistor cells may include 50% active cells, 75% active cells, or the like.

In alternate implementations, other techniques may be included in the process 500 in various combinations, and remain within the scope of the disclosure.

### Conclusion

Although the implementations of the disclosure have been described in language specific to structural features and/or methodological acts, it is to be understood that the implementations are not necessarily limited to the specific features or acts described. Rather, the specific features and acts are disclosed as representative forms of implementing example devices and techniques.

1. An apparatus, comprising:
an element arranged to be located proximate to a semiconductor device and to increase a temperature of at least a portion of the semiconductor device during operation of the semiconductor device.

2. The apparatus of claim 1, wherein the element comprises a polysilicon structure.

3. The apparatus of claim 1, wherein the element is arranged to be located proximate to one or more edges of the semiconductor device and is arranged to increase a temperature of the one or more edges of the semiconductor device during operation of the semiconductor device.

4. The apparatus of claim 1, wherein the element is arranged to reduce a lateral temperature gradient of the portion of the semiconductor device during operation of the semiconductor device.

5. The apparatus of claim 1, wherein the element is arranged to provide a substantially homogeneous temperature distribution across the semiconductor device.

6. The apparatus of claim 1, wherein the element has a power density substantially equal to a power density of the semiconductor device during operation of the semiconductor device.

7. The apparatus of claim 1, wherein the element is switched on concurrently with the semiconductor device and is switched off concurrently with the semiconductor device.

8. A system, comprising:
a semiconductor device; and
a heating element coupled to the semiconductor device, the heating element arranged to increase a temperature of at least a portion of the semiconductor device during operation of the semiconductor device.

9. The system of claim 8, further comprising a switch coupled to the heating element and arranged to switch on the heating element when the semiconductor device switches on and to switch off the heating element when the semiconductor device switches off.

10. The system of claim 8, wherein the semiconductor device comprises a plurality of transistor cells.

11. The system of claim 8, wherein the heating element comprises one or more polysilicon resistors.

12. The system of claim 8, wherein the heating element is arranged to relocate a lateral temperature gradient associated with the portion of the semiconductor device a preselected distance, and wherein a cross-sectional area of the heating element is based on the preselected distance to relocate the lateral temperature gradient.

13. The system of claim 8, wherein an area of the heating element is based on a power density of the semiconductor device during operation of the semiconductor device.

14. The system of claim 8, wherein a metallization layer for the semiconductor device is arranged to energize the heating element.

15. A method, comprising:
locating a heating element proximate to a semiconductor device; and
increasing a temperature of at least a portion of the semiconductor device with the heating element during operation of the semiconductor device.

16. The method of claim 15, further comprising locating the heating element proximate to one or more of the peripheral edges of the semiconductor device.

17. The method of claim 15, further comprising forming the heating element as a part of the semiconductor device.

18. The method of claim 15, further comprising moving a lateral temperature gradient associated with the portion of the semiconductor device a distance substantially equal to a width of the heating element.

19. The method of claim 18, further comprising moving the lateral temperature gradient from a location associated with the portion of the semiconductor device to a location outside a periphery of the semiconductor device.

20. The method of claim 15, further comprising switching on the heating element concurrent to switching on the semiconductor device and switching off the heating element concurrent to switching off the semiconductor device.

21. The method of claim 15, wherein the semiconductor device comprises a matrix of active transistor cells and inactive transistor cells.

22. The method of claim 21, wherein the portion of the semiconductor device has a preselected concentration of active transistor cells within the matrix of active transistor cells and inactive transistor cells.

23. A semiconductor device, comprising:
a matrix of parallel transistor cells; and
a heating element located proximate to a portion of the transistor cells, the heating element arranged to increase a temperature of the portion of the transistor cells during operation of the semiconductor device.

24. The semiconductor device of claim 23, wherein the heating element is located around a periphery of the matrix of parallel transistor cells and is arranged to increase a temperature of transistor cells at the periphery of the matrix.

25. The semiconductor device of claim 23, wherein the heating element is arranged to move a temperature gradient associated with a periphery of the matrix of transistor cells to a location outside the periphery of the matrix.
